(19) United States
(12) Patent Application Publication
(10) Pub. No.: US 2009/0189595 A1
(43) Pub. Date: Jul. 30, 2009

(54) CIRCUIT FOR DETECTING THE DUTY CYCLE OF CLOCK SIGNALS

(75) Inventor: Cord Heinrich Kohsiek, Ellerau (DE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/306,896

(22) PCT Filed: May 30, 2007
(86) PCT No.: PCT/IB07/52033

§ 371 Date: Dec. 29, 2008

(30) Foreign Application Priority Data
Jun. 30, 2006 (EP) 06116341.6

(51) Int. Cl. G01R 23/165

(52) U.S. Cl. 324/76.45

(57) ABSTRACT

A circuit (100) for detecting the duty cycle of clock signals comprises an oscillator (2) whose signal can be changed into a square-wave voltage in a gate (3). In order to obtain a simple construction of the circuit (100) with improved quality of the output signals a low-pass filter (3) is provided whose output signal is situated between “low” and “high”.

The invention relates to a circuit for detecting the duty cycle of clock signals by means of an oscillator whose signal can be converted into a square-wave voltage in a gate.

Electronic circuits including oscillators for generating ever changing signals or output voltages are used in many fields of technology. For example, clock signals are generated by these oscillators to define a clock frequency for a downstream electronic circuit in order to achieve specific objectives. For this purpose an oscillator generates an output signal, which is not yet a square-wave signal as a result of the technical features of the oscillator. For an unambiguous distinction between for example the two states of “high” signals and “low” signals, however, preferably square-wave voltages are suitable, which change between these two states. To this end the signal from an oscillator is applied to a gate in order to be converted into such a square-wave voltage.

US 2003/0058036 A1 describes a method for the demodulation of phase-shifted enciphered signals. Mean values are then formed in a circuit, which are digitized and processed by means of a low-pass filter, an analog-to-digital converter and a controller. In consequence, considerable hardware and software circuitry and cost is necessary to realize this digital signal processing.

From U.S. Pat. No. 6,084,452 is known an electronic circuit by which clock signals can be analyzed. However, the available non-linear components are not very suitable for this purpose. In order to compensate errors that occur during the computation of mean values, a compensation circuit is to be included, which in turn represents additional circuitry and cost.

Furthermore, US 2004/0080350 A1 describes a circuit by which a duty cycle of a symmetrical push-pull signal can be corrected to a desired value. The analog signal used for this purpose, however, cannot for example drive a gate downstream in the circuit.

Based on this state of the art the invention has for its object to provide a circuit that detects the duty cycle of a square-wave signal, evaluates it and notifies in the form of a one-bit signal whether the duty cycle is sufficiently symmetrical.

This object is achieved by means of the characteristic features as claimed in claim 1.

The central idea of the invention is that a low-pass filter is assigned to an oscillator known per se whose signal is converted into a square-wave voltage by means of one or more gates or inverters respectively, and the output signal of the low-pass filter is “low” and “high” depending on the duty cycle of the output signal of the gate. In this way a mean value is formed. Extremely asymmetrical duty cycles of a clock signal can be detected simply and in analog form so as to avoid outputting a wrong clock signal. Especially for this purpose a one-bit signal can be used.

The advantage of the invention consists in that the duty cycle of a square-wave voltage can be analyzed and evaluated without the necessity of incorporating large circuitry or programming, but merely by means of an analog circuit that has components known per se. In this way a changing duty cycle can be detected and for example the reaching of a required value can be announced. As long as the required value has not been reached or has been fallen short of, this can be used for switching off the signal or changing the further processing in order to avoid malfunctioning in circuits downstream in the circuitry and controlled by the same clock signal.

Preferred embodiments of the invention are defined in the subject matter of dependent claims.

In accordance with claim 2 the low-pass filter is advantageously followed by two comparators which check with their inputs the output voltage of the low-pass filter whether the duty cycle is too small, for example has a value between 0% and X%, whether the duty cycle is in order, thus has a value between X% and Y% or whether the duty cycle is too large, thus between Y% and 100%. It will be obvious that the values X and Y can be chosen at will and predefined by the expert as a function of the desired application or measuring accuracy.

To improve the accuracy of the circuit it is proposed in claim 3 that a voltage divider is included to derive the comparator switching thresholds from the supply voltage of the gate that supplies the signal to the low-pass filter.

Preferably, in accordance with claim 4, each comparator comprises a hysteresis which is particularly larger than the AC voltage component on the low-pass filter output. Since the output signal of the low-pass filter can also include remainders of the input signal in the form of a superimposed AC voltage, the comparators would switch a number of times within the range of their switching voltage, perhaps also in the event of a highly asymmetrical duty cycle. Consequently, it would not be possible to process the comparator output signals. This is avoided with such a hysterisis.

In accordance with claim 5 such a hysterisis is formed in an analog method of construction with two further comparators and two flip-flops, that is to say, with electrical circuit components known per se.

An embodiment of the invention will be discussed in further detail hereinafter, in which:

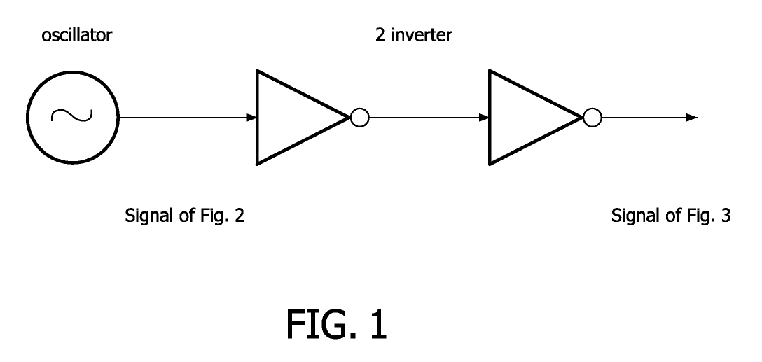

FIG. 1 shows an oscillator with one gate;

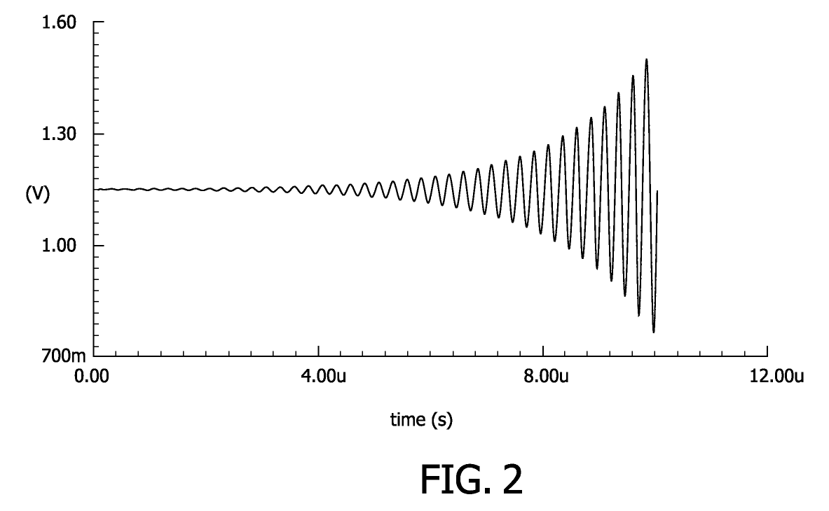

FIG. 2 shows the AC voltage generated by the oscillator;

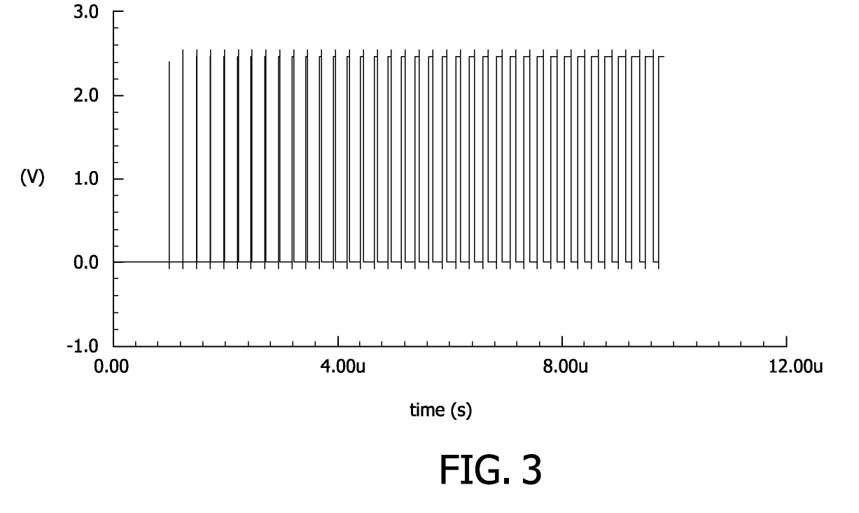

FIG. 3 shows a square-wave voltage with a variable duty cycle;

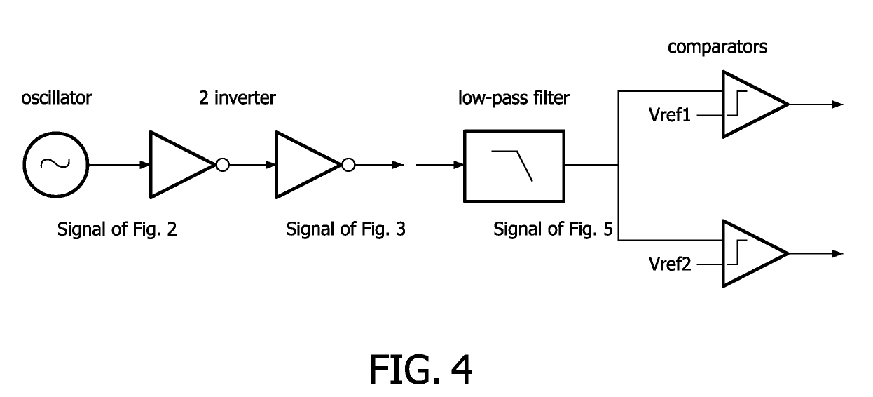

FIG. 4 shows a circuit including a low-pass filter;

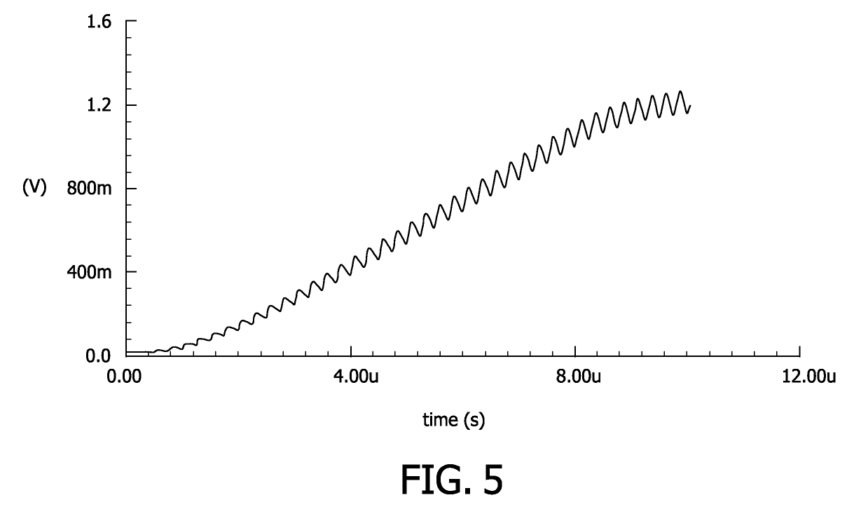

FIG. 5 shows the output signal of the circuit;

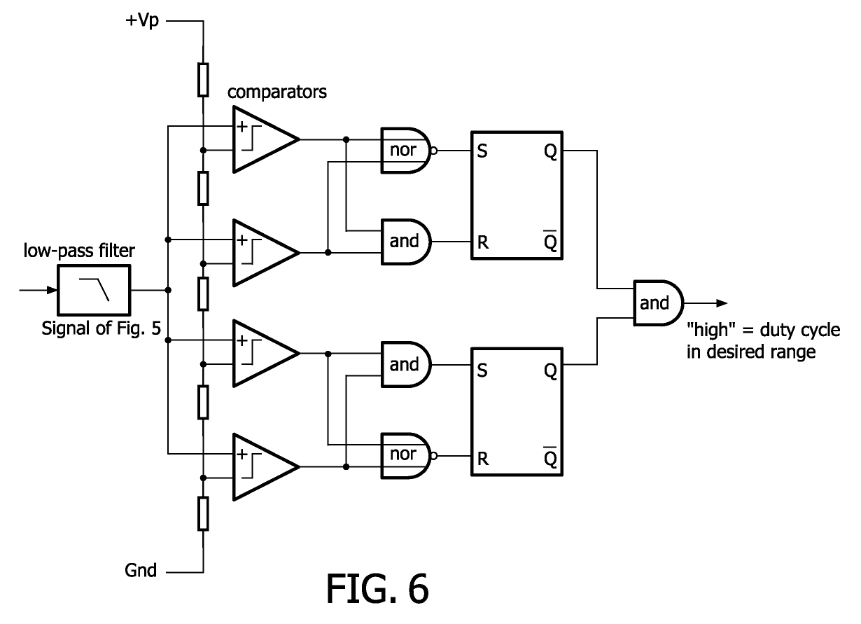

FIG. 6 shows a low-pass filter with hysterisis;

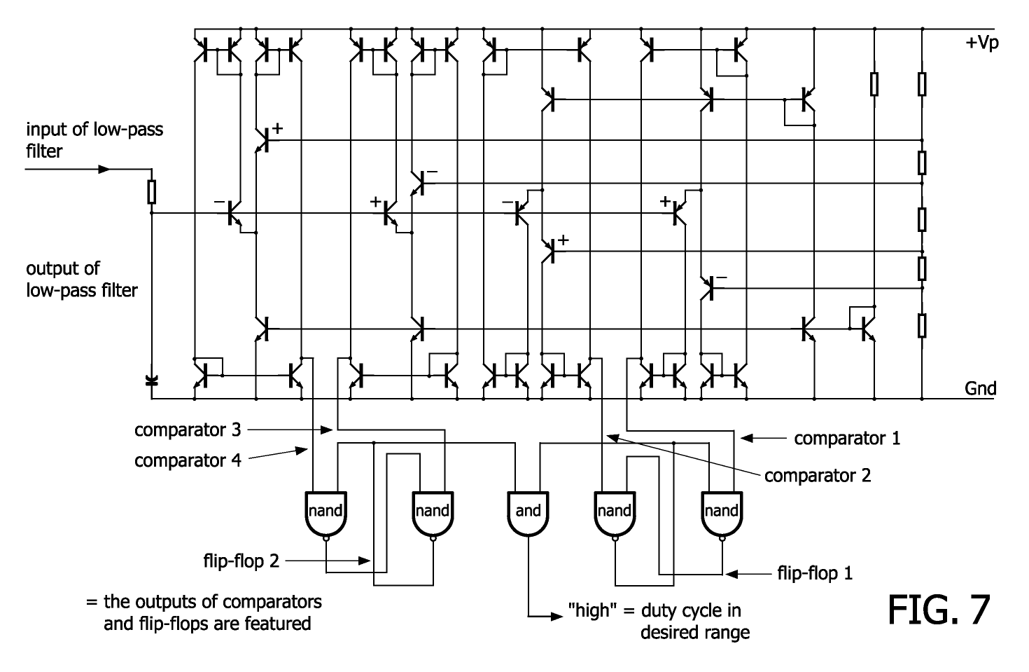

FIG. 7 shows an example of embodiment of the overall circuit with low-pass filter, comparators, hysterisese and switching thresholds; and

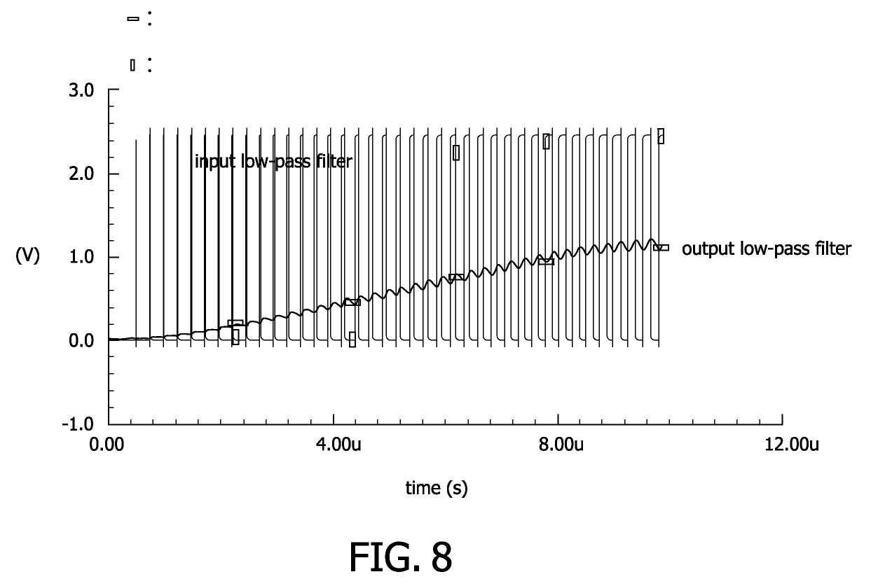

FIGS. 8 to 11 show output signals of the circuit.

In the example of embodiment shown in FIGS. 1 to 11 it is a circuit 100 that comprises analog electrical components known per se such as high-pass or low-pass filters, logic circuits, oscillators and the like. Such a circuit 100 is integrated for example into a microchip or realized on a printed circuit board.

In FIG. 1 an oscillator 1 is shown whose output signal shown in FIG. 2 is applied to a gate 2 or inverter indicated by arrows in order to generate a square-wave voltage shown in FIG. 3, which square-wave voltage can then further be processed in an arbitrary, particularly digital circuit for example for clocking this circuit.

The diagrams each show along the y-axis the amplitude and along the x-axis the time duration in microseconds.

When the oscillator 1 is switched on, its amplitude is first zero and does not reach the desired level until after a plurality of periods, especially when it is an oscillator 1 that starts up slowly, such as for example a quartz oscillator or a high-grade LC oscillator. When the circuit 100 is switched on, the output signal of the gate 2 is either “high” or “low” owing to the lack of the oscillator voltage, an offset voltage on the gate input and the high gate amplification, and, in the event of a rising oscillator voltage, changes to an asymmetrical duty cycle which becomes symmetrical again when the oscillator amplitude rises and changes to the desired duty cycle, generally 50:50 as is shown in FIG. 3.

Such a strongly asymmetrical duty cycle is not processed correctly by all the downstream circuit components, because they are generally not designed to do this. For example with a what is called Power on Reset flip flops which are clocked by a plurality of clock signals can be set to certain states. If the duty cycle of the clock signals is still too asymmetrical at the instant of the Power on Reset to reliably set the flip flops, the circuit will not operate correctly as a result of the flip flops being set wrong. Just as well a frequency divider that is driven by too narrow input spikes will give wrong results.

In order to avoid all this a low-pass filter 3 is assigned to the circuit 100 as is shown in FIG. 4, in order to obtain output signals as shown in FIG. 5. The output signal is then between high and low as defined by the duty cycle. Additionally, two comparators 4a and 4b are provided which with their inputs evaluate the output voltage of the low-pass filter 4 to find whether the duty cycle is too small, too large or is within a desired and preferably adjustable value range and thus satisfies the requirements as to quality. Preferably these comparator thresholds are derived by means of a voltage divider from the supply voltage of the gate 2 which supplies the signal to the low-pass filter 3.

In order to improve the signal quality each comparator 4 additionally comprises a hysterisis, which is larger than the AC voltage component on the low-pass filter output. This hysterisis is formed, as is shown in FIG. 6, by two further comparators 4 and two flip-flops 5a, 5b each. Finally, the comparator output signals are combined by means of a logic gate 6, which forms the obtained output signal into a one-bit magnitude and announces whether the duty cycle of the input voltage satisfies a certain requirement.

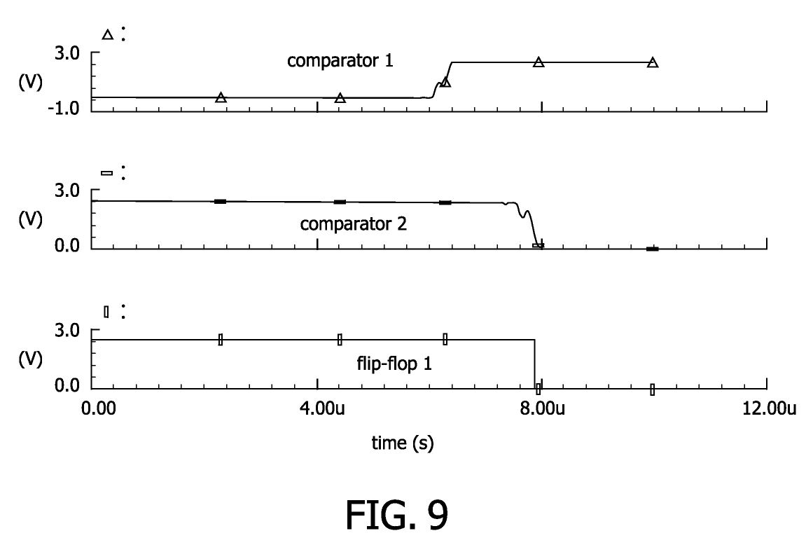

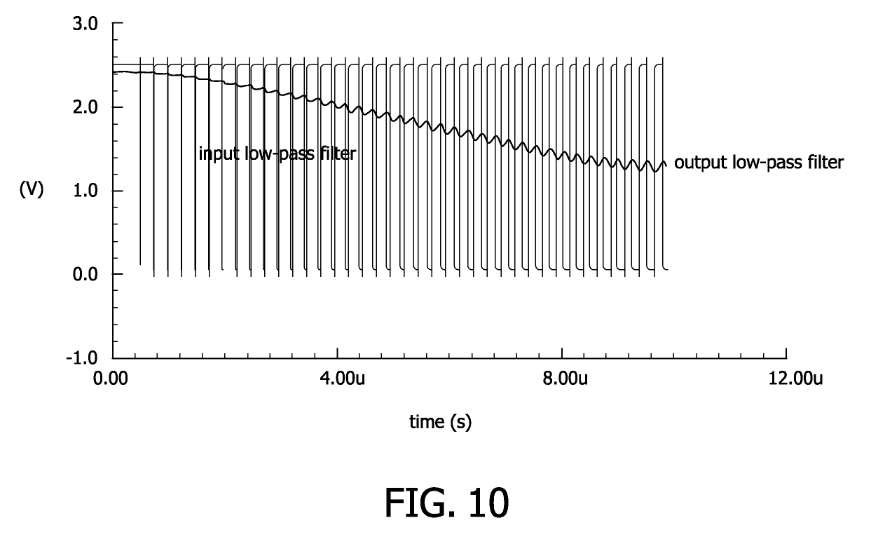

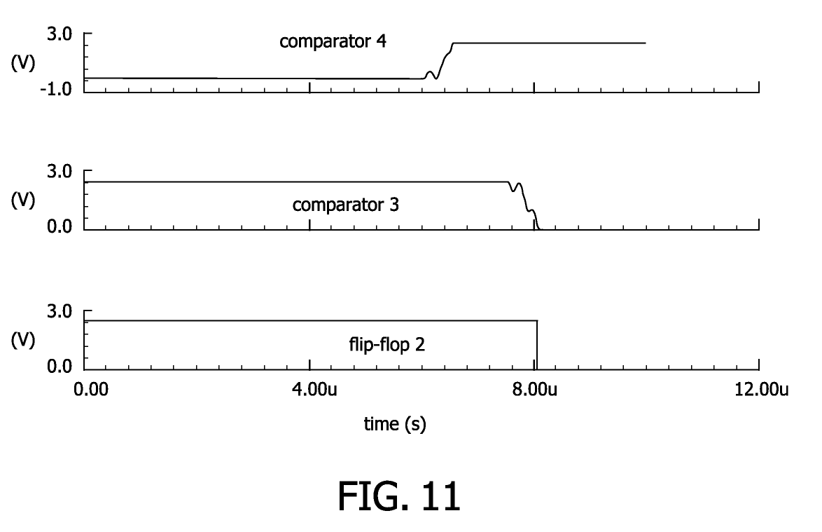

A corresponding block circuit diagram showing circuit elements, minimized logics and analog operation is depicted in FIG. 7. The FIGS. 8 to 11 show the essential signals of the circuit 100, while FIGS. 8 and 9 start with the “low” state and FIGS. 10 and 11 start with the “high” state, each depending on the polarity of the gate offset.

### REFERENCE LIST

100 circuit
1 oscillator
2 gate
3 low-pass filter
4 comparator
5 flip-flop
6 logic gate

1. A circuit for detecting the duty cycle of clock signals, comprising an oscillator whose signal can be changed into a square-wave voltage in a gate, characterized in that a low-pass filter is provided whose output signal is situated between “low” and “high”.

2. A circuit as claimed in claim 1, wherein two comparators are connected downstream of the low-pass filter.

3. A circuit as claimed in claim 2, wherein voltage dividers are assigned to the comparators.

4. A circuit as claimed in claim 3, wherein the voltage dividers are supplied with voltage by the same voltage supply that also supplies the gates connected upstream of the low-pass filter.

5. A circuit as claimed in claim 2, wherein each comparator has a hysterisis.

6. A circuit as claimed in claim 5, wherein the hysterisis is realized by means of two further comparators and two flip-flop circuits.
